(19) United States
(12) Patent Application Publication
(10) Pub. No.: US 2019/0036286 A1
(43) Pub. Date: Jan. 31, 2019

(54) BATTERY BOX STRUCTURE

(71) Applicant: SPRING LITE ELECTRONIC ENTERPRISE CO., LTD., New Taipei City (TW)

(72) Inventor: PEI-JUNG YANG, New Taipei City (TW)

(21) Appl. No.: 15/660,911

(22) Filed: Jul. 26, 2017

(51) Int. Cl. H01R 33/955; G01R 31/36; H01M 6/50; H01M 10/48; H01M 2/10

(52) U.S. Cl. CPC H01R 33/955; G01R 31/3689; H01M 2/1016; H01M 10/488; H01M 6/505

(57) ABSTRACT

A battery box structure includes: a box body, inside thereof having first and second accommodation spaces, two ends of the first accommodation space and two ends of the second accommodation space respectively configured with first positive and first negative conductors and second positive and second negative conductors, bottoms of the first positive, first negative, second positive and second negative conductors respectively passed through the box body and extended out to form first, second, third and fourth terminals, the second terminal having a groove, one side of the groove extended with an engagement portion, the first positive conductor in electric connection with the second negative conductor, the third terminal in combination with a press rod positioned above the groove, and the press rod spaced apart from the groove a preset distant; and a light emitting element, respectively in combination with the first and fourth terminals.

### (a) TECHNICAL FIELD OF THE INVENTION

The present invention relates to a light bulb test device, and more particularly to a battery box structure, in connection with a light bulb and using an elastic sheet as a switch.

### (b) DESCRIPTION OF THE PRIOR ART

In current battery box industry, manufacturers always need to install a light bulb and independent switch on a battery box for test use. However, switch parts cost is increasing, and the switch is only used for test on the battery box and not an essential component. Therefore, these kinds of switches not only cause the cost to be increased but are environmentally unfriendly; even if the switches are recycled, a lot of manpower must be spent, being not convenient.

### SUMMARY OF THE INVENTION

The main object of the present invention is to provide a battery box structure, without needing the installment of a switch element, lowering production cost, shortening manufacturing time, reducing manual switch assembly, and completing the light bulb test with a smallest number of parts.

To achieve the object mentioned above, the present invention proposes a battery box structure, including: a box body, inside thereof configured with a plate, allowing two sides of the plate to form with a first accommodation space and second accommodation space, two ends of the first accommodation space respectively configured with a first positive conductor and first negative conductor, two ends of the second accommodation space a second positive conductor and second negative conductor, bottoms of the first positive conductor, first negative conductor, second positive conductor and second negative conductor respectively passed through the box body and extended out to form a first terminal, second terminal, third terminal and fourth terminal, the second terminal having a groove, one side of the groove extended with an engagement portion, the first positive conductor, the first positive conductor in electric connection with the second negative conductor, the third terminal of the second positive conductor in combination with a press rod, the press rod positioned above the groove of the second terminal, and the press rod spaced apart from the groove a preset distant; and a light emitting element, provided with two conducting lines and a light emitting element, one end of each conducting wire respectively in connection with the light emitting element, and another end thereof respectively in combination with the first terminal and fourth terminal, the first accommodation space and second accommodation space respectively providing for the installment of at least one battery; whereby, the press rod is pressed to be in contact with the groove or selectively in combination with the engagement portion, allowing the light emitting element to be lighted.

### BRIEF DESCRIPTION OF THE DRAWINGS

FIG. 1 is a perspective view of the present invention;

FIG. 2 is a perspective view of the present invention shown in FIG. 1 viewed from another angle; and

FIG. 3 is an exploded view of the present invention.

### DETAILED DESCRIPTION OF THE PREFERRED EMBODIMENTS

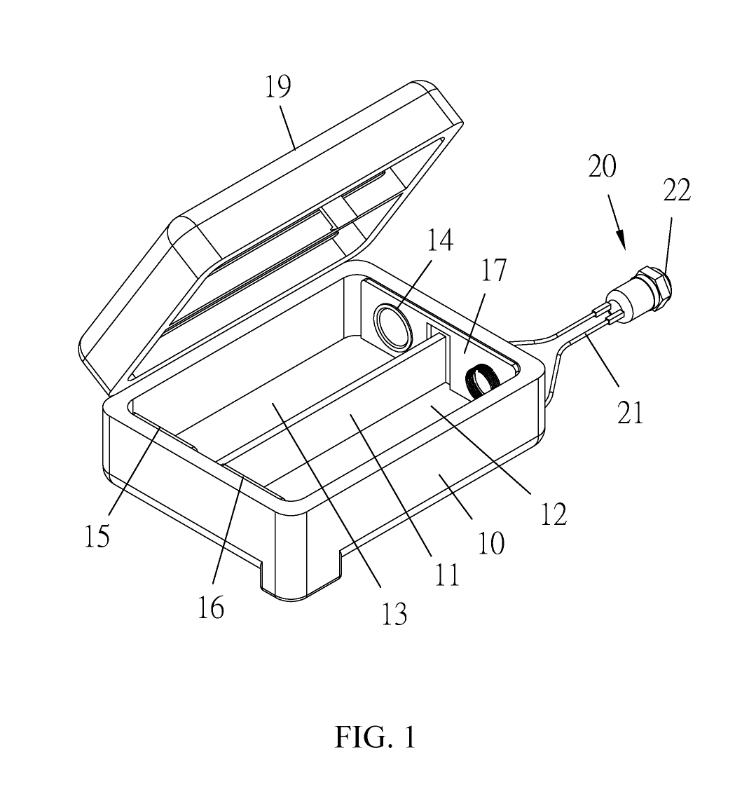

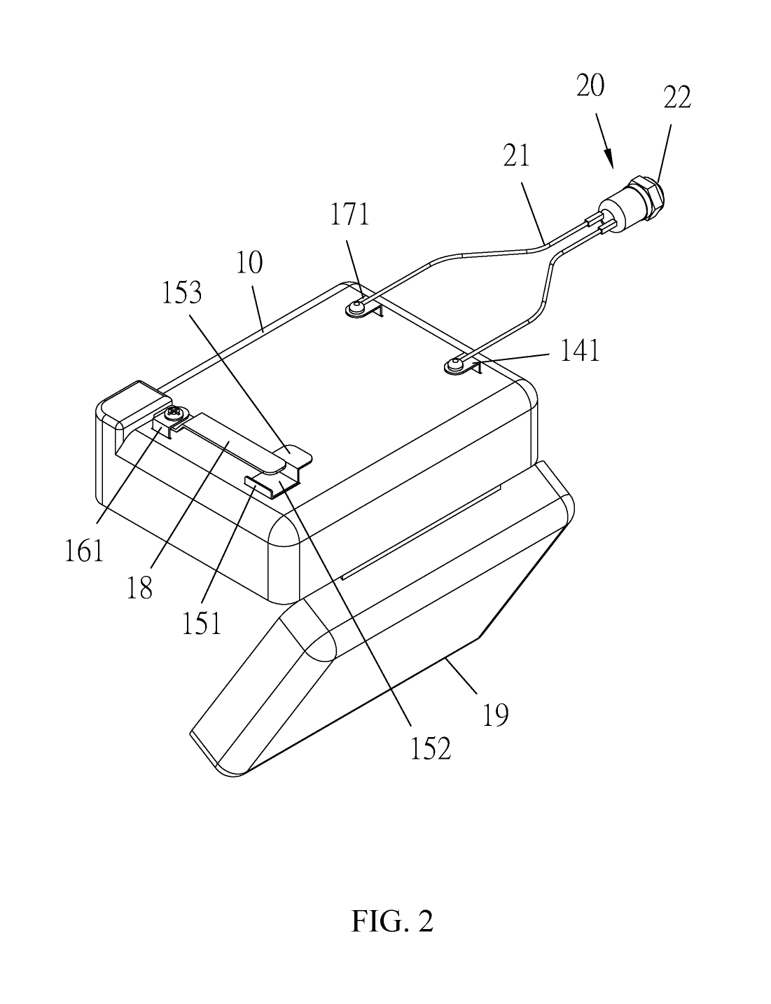

Referring to FIGS. 1 and 2, a battery box structure 1 of the present invention includes a box body 10 and light emitting unit 20.

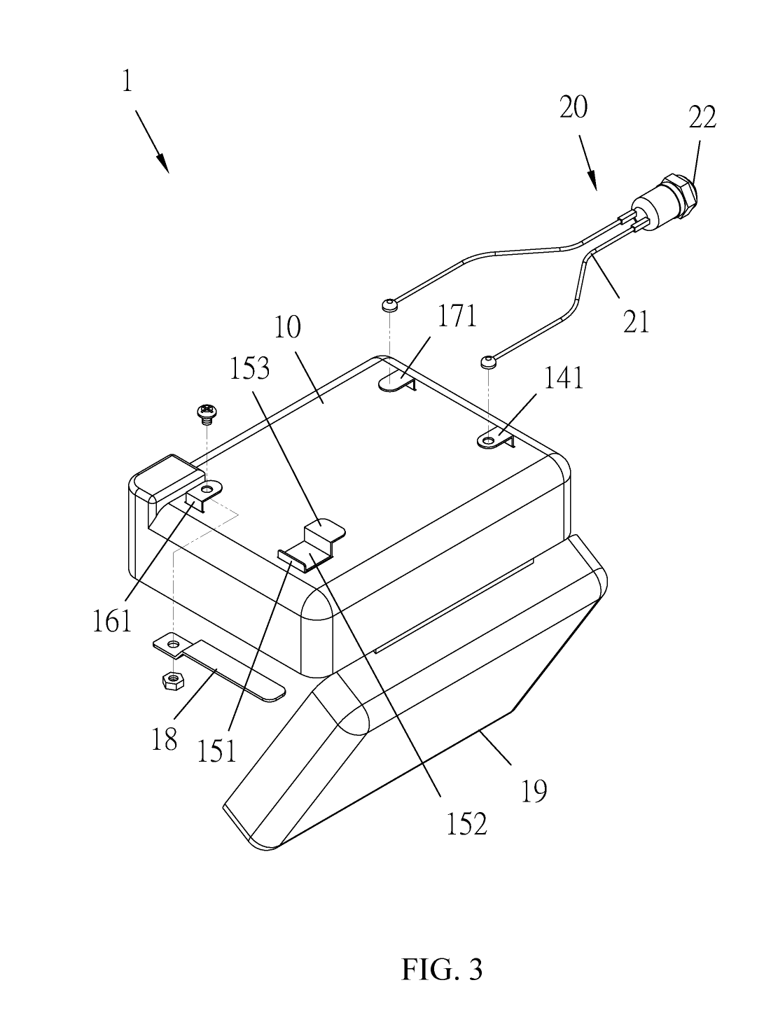

Referring FIGS. 1 to 3, the inside of the box body 10 is configured with a plate 11, allowing a first accommodation space 12 and second accommodation space 13 to be respectively formed at two sides of the plate 11, where the two ends of the first accommodation space 12 are respectively configured with a first positive conductor 14 and first negative conductor 15, and the two ends of the second accommodation space 13 a second positive conductor 16 and second negative conductor 17, where the bottoms of the first positive conductor 14, first negative conductor 15, first positive conductor 16 and second negative conductor 17 are respectively passed through the box body 10 and extended out thereof to form a first terminal 141, second terminal 151, third terminal 161 and fourth terminal 171. In particular, the second terminal 151 has a groove 152, one side of which is extended out with an engagement portion 153; the first positive conductor 14 and second negative conductor 17 are in electric connection with each other; the third terminal 161 of the second positive conductor 16 is in combination with a press rod 18, which may be an elastic sheet and is positioned above the groove 152 of the second terminal 151, with the press rod 18 being spaced apart from the groove 152 a preset distance.

The first terminal 141, third terminal 161 and fourth terminal 171 mentioned above are respectively 90 degrees bended, thereby allowing the third terminal 141 to be in combination with the press rod 18, the first terminal 141 and fourth terminal 171 to be respectively coupled to a conducting line 21.

A cover 19 is coupled pivotally to one side of the box body 10 mentioned above, and the first accommodation space 12 and second accommodation space 13 are sealed by the cover 19.

The light emitting unit 20 is provided with the two conducting lines 21 and a light emitting element 22, one end of each conducting line 21 is respectively in connection with the light emitting element 22, another end thereof is respectively coupled to the first terminal portion 141 and fourth terminal 171, and the first accommodation space 12 and second accommodation space 13 are respectively provided for the installment of at least one battery (not shown in the figures). Whereby, the press rod 18 is pressed to be in contact with the groove 152 or selectively in combination with the engagement portion 153 to make the light emitting element 22 light.

I claim:

1. A battery box structure, comprising:
a box body, inside thereof configured with a plate, allowing two sides of said plate to form with a first accommodation space and second accommodation space, two ends of said first accommodation space respectively configured with a first positive conductor and first negative conductor, two ends of said second accommodation space a second positive conductor and second negative conductor, bottoms of said first positive conductor, first negative conductor, second positive conductor and second negative conductor respectively passed through said box body and extended out to form a first terminal, second terminal, third terminal and fourth terminal, said second terminal having a groove, one side of said groove extended with an engagement portion, said first positive conductor, said first positive conductor in electric connection with said second negative conductor, said third terminal of said second positive conductor in combination with a press rod, said press rod positioned above said groove of said second terminal, and said press rod spaced apart from said groove a preset distant; and
a light emitting element, provided with two conducting lines and a light emitting element, one end of each said conducting wire respectively in connection with said light emitting element, and another end thereof respectively in combination with said first terminal and fourth terminal, said first accommodation space and second accommodation space respectively providing for the installment of at least one battery; whereby, said press rod is pressed to be in contact with said groove or selectively in combination with said engagement portion, allowing said light emitting element to be lighted.

2. The structure according to claim 1, wherein said first, third and fourth terminals are respectively bended a right angle.

3. The structure according to claim 1, wherein a cover is couple pivotally to one side of said box body, and said first and second accommodation spaces are sealed by said cover.
